(19) United States
(12) Patent Application Publication
(10) Pub. No.: US 2011/0266576 A1
(43) Pub. Date: Nov. 3, 2011

(54) Optoelectronic Semiconductor Component

(75) Inventors: Moritz Engl, Regensburg (DE); Joerg Erich Sorg, Regensburg (DE); Thomas Zeiler, Nittendorf (DE); Michael Reich, Regensburg (DE); Ulrich Streppel, Regensburg (DE)

(73) Assignee: OSRAM OPTO SEMICONDUCTORS GMBH, Regensburg (DE)

(21) Appl. No.: 13/127,213

(22) PCT Filed: Oct. 27, 2009
(86) PCT No.: PCT/DE2009/001504

§ 371 Date: Jul. 19, 2011

(30) Foreign Application Priority Data
Oct. 30, 2008 (DE) 10 2008 054 029.3

(51) Int. Cl. H01L 33/50

(52) U.S. Cl. 257/98; 438/29; 257/E33.06

(57) ABSTRACT

An optoelectronic semiconductor device at least one radiation-emitting semiconductor chip (3); at least one converter element (4) disposed downstream of the semiconductor chip (3) and serving for converting electromagnetic radiation emitted by the semiconductor chip (3) during operation, wherein the converter element (4) emits colored light upon irradiation with ambient light; a means for diffusely scattering light (5), which is designed to scatter ambient light impinging on the device in a switched-off operating state of the device in such a way that a light exit area (62) of the device appears white.

An optoelectronic semiconductor device is specified.

This patent application claims the priority of German patent application 10.2008 054 029.3, the disclosure content of which is hereby incorporated by reference.

One object to be achieved consists in specifying an optoelectronic semiconductor device which appears in accordance with a predeterminable color impression for an external observer upon observation of a light exit area of the optoelectronic semiconductor device in the switched-off operating state.

In accordance with at least one embodiment of the optoelectronic semiconductor device, the device comprises at least one radiation-emitting semiconductor chip. The radiation-emitting semiconductor chip can be a luminescence diode chip, for example. The luminescence diode chip can be a light-emitting or laser diode chip that emits radiation in the range from ultraviolet to infrared light. Preferably, the luminescence diode chip emits light in the visible or ultraviolet range of the spectrum of the electromagnetic radiation.

In accordance with at least one embodiment, at least one converter element for converting electromagnetic radiation emitted by the semiconductor chip during operation is disposed downstream of the radiation-emitting semiconductor chip in the emission direction. The converter element emits colored light upon irradiation with ambient light—if the latter comprises a wavelength component suitable for the excitation of a conversion substance in the converter material. The converter element is arranged on or at a radiation exit area of the semiconductor chip. During the operation of the optoelectronic semiconductor device, the conversion element converts light having one wavelength into light having another wavelength. By way of example, the converter element converts blue light primarily emitted by the semiconductor chip partly into yellow light, which can then be mixed together with the blue light to form white light.

The converter element therefore has the function of a light converter during the operation of the semiconductor device. The converter element can be applied to the semiconductor chip and thus be directly in contact with the semiconductor chip. By way of example, this can be achieved by adhesively bonding the converter element onto the semiconductor chip or by means of a screen printing method. However, there is also a possibility of the converter element being in contact with the semiconductor chip only indirectly. That can mean that a gap is formed between the converter element/semiconductor chip interface and so the converter and the semiconductor chip do not touch one another. The gap can be filled with a gas, for example air.

The converter element can be formed with a silicone, an epoxide, a mixture of silicone and epoxide, or a transparent ceramic, into which particles of a conversion substance are introduced.

In accordance with at least one embodiment, the device has a light exit area. Electromagnetic radiation emitted by the semiconductor chip is coupled out from the device through an optical element, for example. The optical element of the device then has a radiation transmitting opening via which the radiation is coupled out from the device. The radiation transmitting opening has an outer area which faces away from the semiconductor chip and which forms the light exit area of the device. The optical element can be a lens or else a simple covering plate. Furthermore, it is possible for the optical element to be formed by a potting that encloses or encapsulates the semiconductor chip.

Furthermore, the optoelectronic semiconductor device comprises a means for diffusely scattering light, which is designed to scatter ambient light impinging on the device in a switched-off operating state of the device in such a way that the light exit area of the device does not appear in the color of the converter element, that is to say yellow, for example. Preferably, the light coupling-out area does not appear colored, but rather white. A body appears white if, for example, the entire solar spectrum is scattered. If ambient light is incident on the device, then the means for diffusely scattering light scatters the ambient light in such a way that it appears white to an external observer after the scattering by the means. In this case, it is possible for the means for diffusely scattering light to be formed from a single element. Moreover, it is also possible for the means for diffusely scattering light to consist of a plurality of components, each of which by themselves are able to diffusely scatter light.

In accordance with at least one embodiment of the opto-electronic semiconductor device, the device comprises at least one radiation-emitting semiconductor chip, at least one converter element disposed downstream of the semiconductor chip and serving for converting electromagnetic radiation emitted by the semiconductor chip during operation, wherein the converter element emits colored light upon irradiation with ambient light. Furthermore, the optoelectronic semiconductor device comprises a means for diffusely scattering light. The means for diffusely scattering light is designed to scatter ambient light impinging on the device in a switched-off operating state of the device in such a way that a light exit area of the device appears white.

In this case, the optoelectronic semiconductor device described here is based on the insight, inter alia, that in the switched-off operating state of the device the semiconductor device appears colored to an external observer if the described means for diffusely scattering light is not present. In this case, the light coupling-out area of the device appears colored on account of the converter element.

The converter element therefore re-emits colored light upon irradiation with ambient light since the ambient light likewise contains exciting components for the converter element. By way of example, the converter element converts impinging blue light into yellow light. Therefore, at its light coupling-out area, the device appears in a different color in the switched-off operating state than in the switched-on operating state.

In order then to avoid such a disturbing colored color impression, the device described here makes use of the concept of positioning in a targeted manner a means for diffusely scattering light at least one location in the beam path of the optoelectronic semiconductor device. The beam path is the path covered by the electromagnetic radiation emitted by the semiconductor chip until it is coupled out through the light exit area of the device. The introduced means for diffusely scattering light in the beam path has the effect that light incident from outside through the light coupling-out area is scattered before it is incident on the converter element. Since the means for diffusely scattering light scatters the entire spectrum of the externally incident ambient light, this light appears white. Although part of the light can impinge on the converter element and is re-emitted in colored fashion, this re-emitted light is also in turn scattered upon passing through the means for diffusely scattering light and mixes with the scattered ambient light. Consequently, an observer sees the colored light re-emitted by the converter element together with the light scattered white by the means for diffusely scattering light. Since light can emerge from the device only via the light exit area, the color impression is defined only by the light coming from the exit area. The larger, then, the ratio of scattered white to re-emitted colored light, the whiter the overall impression of the light exit area of the device for an external observer.

The external color impression of the light exit area of the device can furthermore be set especially advantageously in a simple manner by virtue of the fact that the means for diffusely scattering light comprises a plurality of components and the individual components of the means for diffusely scattering light can be fitted at different locations of the device and in different concentrations.

In accordance with at least one embodiment of the optoelectronic semiconductor device, the means for diffusely scattering light comprises a matrix material into which radiation-scattering particles (also called diffuser particles) are introduced. Preferably, the matrix material is a material which is transparent to the electromagnetic radiation generated by the semiconductor chip in order to ensure that radiation is coupled out from the device to the highest possible extent during the operation of the device. The matrix material can be a transparent plastic material such as silicone, an epoxide or a mixture of silicone and epoxide. By way of example, the matrix material contains one of said materials. Radiation-scattering particles that diffusely scatter radiation incident on the matrix material are introduced into the matrix material.

In accordance with at least one embodiment of the optoelectronic semiconductor device, the radiation-scattering particles comprise at least particles composed of the materials silicon dioxide (SiO₂), ZrO₂, TiO₂ and/or AlₓO_{y}. By way of example, the aluminum oxide can be Al₂O₃. The radiation-scattering particles are mixed with the matrix material before being introduced into the semiconductor device. Preferably, the radiation-scattering particles are distributed in the matrix material in such a way that the concentration of the radiation-scattering particles in the cured matrix material is uniform. Preferably, the light reflected by the cured matrix material is isotropically reflected and scattered.

In accordance with at least one embodiment of the opto-electronic semiconductor device, the concentration of the radiation-scattering particles in the matrix material is more than 6% by weight. It has been possible to show that, starting from such a concentration of the radiation-scattering particles, the white color impression for an external observer is generated and the scattered white light is superimposed on the colored, for example yellow, re-emitted light from the converter.

In accordance with at least one embodiment of the optoelectronic semiconductor device, the converter element and the means for diffusely scattering light are in direct contact with one another. By way of example, the means for diffusely scattering light comprises a light-scattering film. That is to say that, along the radiation exit direction of the semiconductor device, the film directly follows the converter element. By way of example, the film is adhesively bonded onto the converter element. Preferably, neither a gap nor an interruption is formed at the converter/film interface. In order to produce the film, radiation-scattering particles, for example particles composed of Al₂O₃, can be introduced into the material of the light-scattering film prior to curing.

In accordance with at least one embodiment of the optoelectronic semiconductor device, the means for diffusely scattering light covers the converter element at all exposed outer areas of the converter element. Preferably, the means for diffusely scattering light comprises a layer composed of a matrix material which is mixed with radiation-scattering particles. After curing, the matrix material forms a layer that covers the converter element at all exposed outer areas. Advantageously, a highest possible proportion of ambient light incident in the device is thus already scattered out of the device by the layer without first impinging on the converter element. Since the layer also covers all exposed side areas of the converter element, this prevents the side areas of the converter element from re-emitting colored light. In this way, a highest possible white proportion is generated in the reflected light.

In accordance with at least one embodiment of the optoelectronic semiconductor device, the means for diffusely scattering light comprises an optical element, which forms a lens at least in places. By way of example, the matrix material mixed with radiation-scattering particles of the means for diffusely scattering light is formed with a silicone that is transparent to electromagnetic radiation. After the curing of the matrix material, a lens in the form of a converging lens can form. Furthermore, it is likewise possible for the cured lens material to be formed in lens-type fashion only in the region of the light exit area. The lens of the optoelectronic semiconductor device provides for efficient coupling-out of the radiation coupled out from the device. By shaping the means for diffusely scattering light to form a lens, a double function is fulfilled. Firstly, the means improves the coupling-out of the radiation, and secondly it provides for the scattering of the impinging ambient light to form white light. Furthermore, light which passes into the device and is re-emitted in colored, for example yellow, fashion by the converter is diffusely scattered upon emerging from the device by the radiation-scattering particles contained in the lens. The scattering of the yellow light once again intensifies the white proportion in the coupled-out light spectrum.

In accordance with at least one embodiment of the optoelectronic semiconductor device, the means for diffusely scattering light comprises a roughening of a light passage area of a light-transmissive body. The light-transmissive body can be a lens, a plate, a cover of the device or the like. Preferably, the roughening is a roughening according to the standard VDI 3400, in particular of the types N4 to N10. By way of example, the roughening has, inter alia, an average depth of 1 to 2 μm, preferably of 1.5 μm. Firstly, the roughening diffusely scatters colored light re-emitted by the converter element; secondly, the roughening scatters incident ambient light in such a way that the light exit area of the optoelectronic semiconductor device appears white. Furthermore, it is likewise possible, however, for the means for diffusely scattering light to comprise, alongside the roughening of the light passage area, a further diffusely scattering component, which intensifies the effect mentioned.

In accordance with at least one embodiment of the optoelectronic semiconductor device, the means for diffusely scattering light comprises microstructures. By way of example, the microstructures are honeycomb structures which are embodied in a planar fashion and which are applied as a layer on the light coupling-out area of the lens by means of a screen printing process, a thermal transfer method or a UV replication. Likewise, the microstructures can have a form and constitution deviating from the honeycomb structure and are therefore not fixedly defined in terms of their structure. The microstructures can also have configurations which vary among one another and/or which arise randomly. Preferably, the layer thickness is at least 10 μm. The microstructures have a diffractive effect with regard to the electromagnetic radiation impinging on them. Furthermore, no diffraction of the impinging radiation via the microstructures takes place. Therefore, the microstructures do not form diffraction gratings, for example.

In accordance with at least one embodiment of the optoelectronic semiconductor device, the means for diffusely scattering light comprises a light-scattering plate, which laterally projects beyond the converter element. Preferably, the light-scattering plate is rigid. By way of example, the plate is formed with a matrix material which is mixed with radiation-scattering particles and which is cured to form the plate. The light-scattering plate can also be formed with a ceramic material. It is likewise conceivable for that side of the plate which faces away from the semiconductor chip and on which the ambient light impinges to be roughened and, by virtue of such a configuration of the plate, for the impinging ambient light to be diffusely backscattered and coupled out from the device. Preferably, the light-scattering plate and the converter element are in direct contact. In order to avoid a situation in which colored radiation laterally reflected by the converter element passes out of the device and, at the same time, as little ambient light as possible is incident on the converter element, the light-scattering plate laterally projects beyond the converter element. It is also possible for the plate additionally to laterally project beyond the semiconductor chip besides the converter element. Preferably, the light-scattering plate projects beyond the semiconductor chip by 200 μm to 500 μm, particularly preferably by 300 μm to 400 μm, for example by 350 μm. Preferably, the light-scattering plate has a thickness of 100 μm to 1 mm, preferably of 300 μm to 800 μm, for example of 500 μm. Advantageously, by virtue of such a configuration of the means for diffusely scattering light, a highest possible proportion of the ambient light is diffusely scattered, as a result of which the light exit area appears white.

In accordance with at least one embodiment of the optoelectronic semiconductor device, the means for diffusely scattering light comprises a film, which is applied on an outer area of a lens. The outer area is that side of the surface of the lens which faces away from the semiconductor chip, and forms the light exit area. The means for diffusely scattering light is applied to the light exit area of the lens for example in the form of a thin-layered film. Preferably, the film is fixed on the lens by means of adhesive bonding. The thin-layered film likewise contains radiation-scattering particles besides the matrix material and thereby provides for a diffuse reflection of incident ambient light and, at the same time, a diffuse scattering of the colored light which is reflected by the converter element and which is likewise coupled out from the device through the lens.

Furthermore, a method for producing an optoelectronic semiconductor device is specified. A device described here can be produced by means of the method. That is to say that all features disclosed in conjunction with the device are also disclosed for the method, and vice versa.

In accordance with at least one embodiment of the method, firstly a carrier element is provided. The carrier element can be a film, for example.

In a second step, a converter element is formed on the carrier element by means of a screen printing process. After a first stencil has been applied, by means of the screen printing process the material of the converter element is applied to the carrier element by blade coating, for example. After application and possible curing of the material, the first stencil is removed from the carrier element. The material for the converter element can be, for example, a layer comprising silicone or composed of a transparent ceramic into which converter particles are introduced.

In a third step, using a second stencil applied to the carrier element, by means of a second screen printing process, a means for diffusely scattering light is applied, as a second layer, to all exposed outer areas of the converter element. The means for diffusely scattering light covers the converter element at all exposed side areas and the top side facing away from the carrier element. The material can be applied by blade coating, for example, and then cured.

After the detachment of the carrier element and the second stencil from the composite assembly consisting of converter element and second layer, the composite assembly is applied on the radiation-emitting semiconductor chip.

The device described here and also the method described here are explained in greater detail below on the basis of exemplary embodiments and with reference to the associated figures.

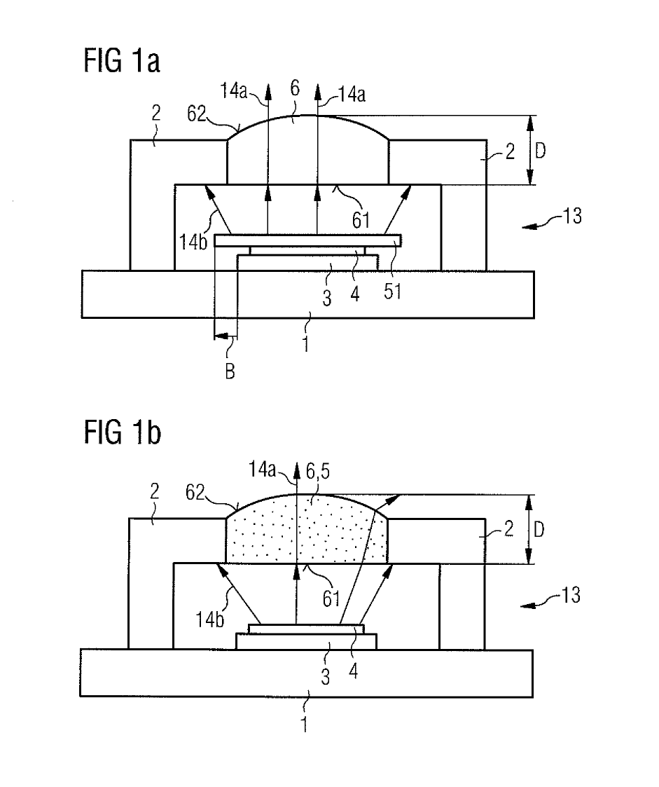

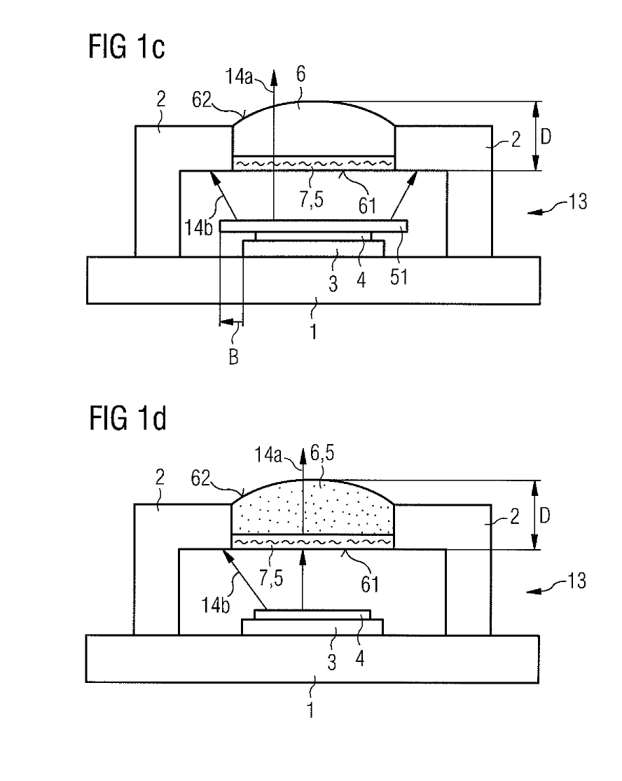

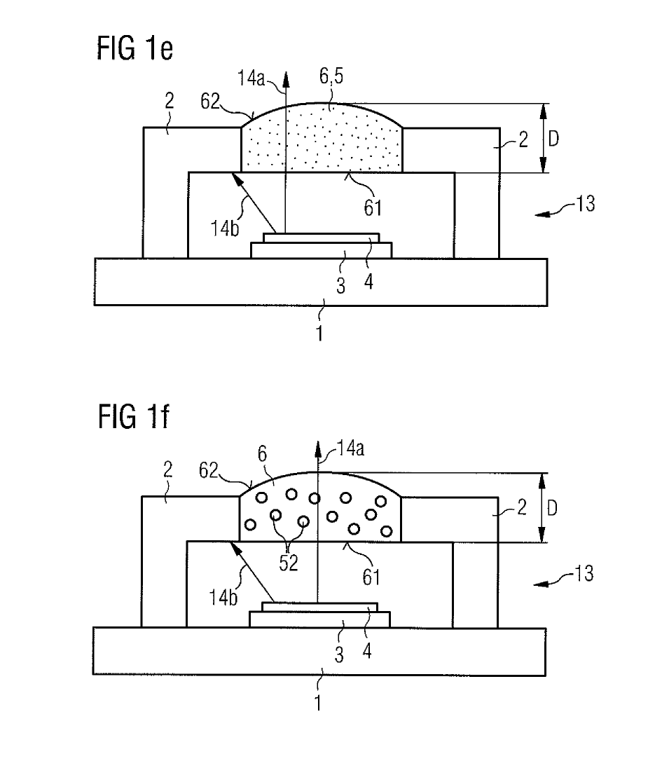

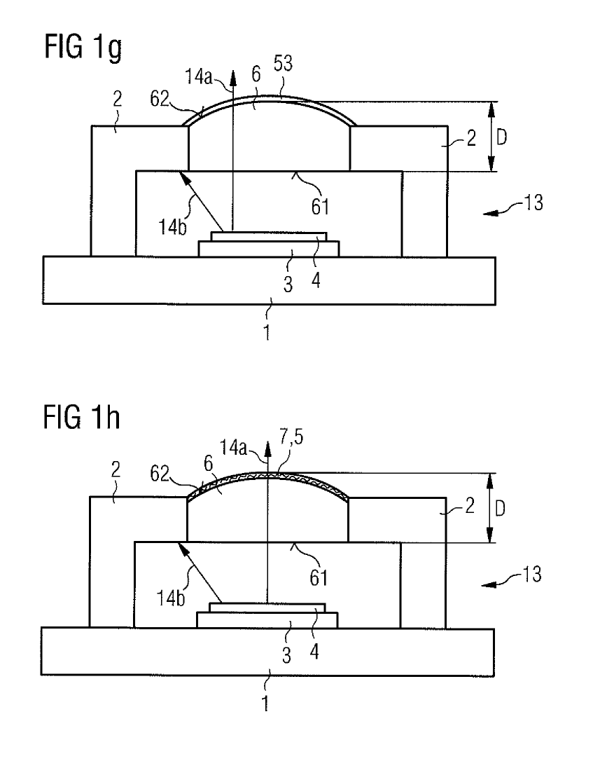

FIGS. 1a to 1h show, in schematic sectional illustrations, exemplary embodiments of an optoelectronic device described here.

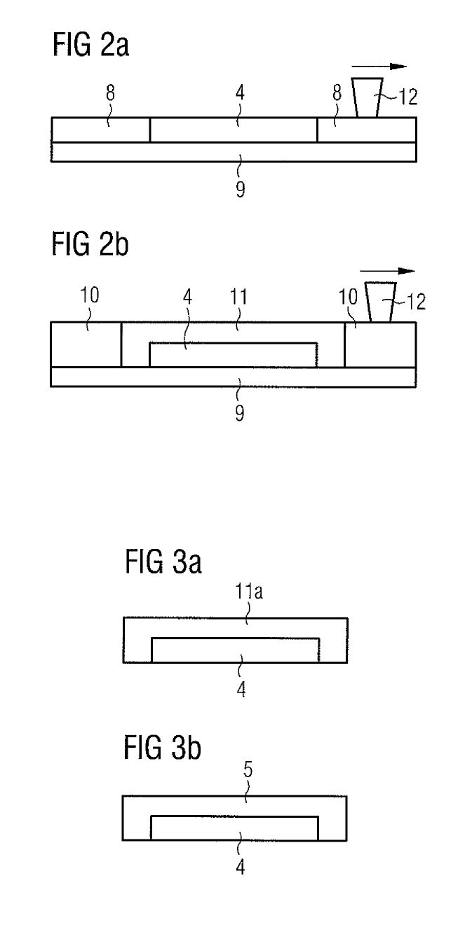

FIGS. 2a, 2b, 3a and 3b show individual manufacturing steps for the production of at least one exemplary embodiment of a device described here.

In the exemplary embodiments and the figures, identical or identically acting constituent parts are in each case provided with the same reference symbols. The elements illustrated should not be regarded as true to scale; rather, individual elements may be illustrated with an exaggerated size in order to afford a better understanding.

FIG. 1a illustrates, on the basis of a schematic sectional illustration, an optoelectronic semiconductor device described here, comprising a basic body 13 consisting of a carrier 1 and a housing 2 fitted thereon. Within the housing 2, a semiconductor chip is applied on the surface of the carrier 1.

The carrier 1 and the housing 2 can be formed with a plastic or a ceramic. The carrier 1 is embodied as a printed circuit board or a leadframe of the device.

The semiconductor chip 3 is electrically conductively connected to the carrier 1. The converter element 4 is applied on the semiconductor chip 3, said converter element, in the switched-on state of the device, converting the radiation primarily emitted by the semiconductor chip 3 into radiation having a different wavelength. In the present example, the converter element 4 is an optical CLC layer (chip level conversion layer), which partly converts the blue light primarily emitted by the semiconductor chip 3 into yellow light. Furthermore, the conversion element 4 re-emits externally incident ambient light and converts, for example, blue light contained in the ambient light into yellow light. The converter element 4 can be a layer, formed with silicone or composed of transparent ceramic, into which converter particles are introduced.

A light-scattering plate 51 is applied on the conversion element 4. The material of the light-scattering plate 51 is silicone that was mixed with radiation-scattering particles composed of aluminum oxide prior to curing to form the plate. The concentration of the aluminum oxide particles in the light-scattering plate 51 is 6% by weight. With such a concentration, the most distinct effects were obtained with regard to the white appearance for an external observer in the switched-off operating state of the device. The light-scattering plate 51 does not cover the side areas of the converter element 4. The lateral extent of the light-scattering plate 51 is chosen to be greater than the lateral extent of the converter element 4, such that the light-scattering plate 51 projects beyond not only the converter element 4 but likewise the semiconductor chip 3 in its lateral extent. The light-scattering plate 51 laterally projects beyond the semiconductor chip 3 by the length B, which amounts to at least 10% of the side length of the semiconductor chip 3. In the present case, the length B is 200 μm. In the switched-off operating state of the optoelectronic semiconductor device, this has the advantage that as little ambient light as possible is incident on the converter element 4 and the light reflected out of the optoelectronic semiconductor device is therefore predominantly white.

Furthermore, FIG. 1a shows an optical element embodied in the form of a lens 6, said optical element being fitted into the housing 2. The lens 6 provides for efficient coupling-out of the electromagnetic radiation re-emitted, scattered or emitted from the device. Only the radiation proportion 14a of the total radiation, which radiation proportion impinges on a light entrance area 61 of the lens 6, is coupled out from the device through the lens 6 via a light exit area 62. The light entrance area 61 is the part of the outer area of the lens 6 which faces the semiconductor chip 3. The light exit area 62 is the part of the outer area of the lens 6 which faces away from the semiconductor chip 3. The lens 6 has a thickness D. The thickness D is the maximum distance between the light entrance area 61 and the light exit area 62 in a direction perpendicular to that surface of the carrier 1 which faces the lens 6. The radiation proportion 14B, which does not impinge on the light entrance area 61, is not coupled out from the device. In the present exemplary embodiment, the lens 6 is formed from a silicone and transparent to electromagnetic radiation. The lens 6 contains no radiation-scattering particles. The electromagnetic radiation that has passed into the device and the electromagnetic radiation emitted by the semiconductor chip 3 during operation are coupled out exclusively by the lens 6 since both the carrier 1 and the housing 2 are radiation-opaque.

FIG. 1b shows an optoelectronic semiconductor device in which the means for diffusely scattering light 5 is the lens 6. For this purpose, the material of the lens, in the present exemplary embodiment a silicone, was mixed with radiation-scattering particles composed of aluminum oxide in a concentration of 0.2 to 1% by weight, preferably of 0.4 to 0.8, in the present case of 0.6, % by weight, wherein the lens 6 has a thickness D of 1.5 mm.

FIG. 1c shows, as in FIG. 1a, a light-scattering plate 51 applied on the converter element 4. In addition, alongside the light-scattering plate 51, the light entrance area 61 of the lens 6 is roughened. The average depth of the roughening 7 is 1 to 2 μm, in the present case 1.5 μm. In FIG. 1c, the means for diffusely scattering light 5 comprises both the light-scattering plate 51 and the roughening 7 and thus consists of two components for diffusely scattering light.

FIG. 1d shows a further possibility for combination of the individual components of the means for diffusely scattering light 5. As already illustrated in FIG. 1b, aluminum oxide particles with a concentration of 0.2 to 1% by weight, preferably of 0.4 to 0.8% by weight, in the present case of 0.6% by weight, are introduced into the material of the lens 6, wherein the thickness D of the lens 6 is 1.5 mm. Furthermore, the means for diffusely scattering light 5 additionally comprises the roughening 7 at the radiation entrance area 61 of the lens 6. Through such a combination, both components intensify the diffusely scattering effect on the incident ambient light.

FIG. 1e shows a lens 6 consisting of a clear silicone, in which the light exit area 62 was encapsulated with a light-scattering material by the use of a two-component injection-molding process. The light-scattering material forms a layer around the light exit area 62 of the lens 6 and together with the lens 6 represents the means for diffusely scattering light 5. The diffuse material is once again a silicone that was mixed with radiation-scattering particles composed of aluminum oxide. In the present exemplary embodiment, the concentration of the aluminum oxide particles is 0.5% by weight, wherein the layer thickness is ideally 50 to 100 μm, in the present case 75 μm.

In FIG. 1f, a layer having microstructures 52, which assumes the physical role of the means for diffusely scattering light 5, is applied on the light exit area 62 of the lens 6. The present exemplary embodiment involves a layer having microstructures 52 embodied in planar fashion in a honeycomb structure, which is applied as a layer to the light exit area 62 of the lens 6 by means of screen printing, a thermal transfer printing method or UV replication. The layer thickness is 50 μm in the present case.

FIG. 1g shows an optoelectronic semiconductor device in which the means for scattering light 5 was adhesively bonded in the form of a film 53 onto the light exit area 62 of the lens 6. The film 53 can be a thin layer in the form of a film which is formed with a silicone. Preferably, the film 53 has a thickness of 30 to 500 μm. In the present exemplary embodiment, the film 53 was chosen with a thickness of 250 μm. Particles composed of aluminum oxide in a concentration of 0.5 to 1% by weight, in the present case of 0.75% by weight, are introduced in the film 53. In this case, the film 53 serves as means for diffusely scattering light.

FIG. 1h shows an optoelectronic semiconductor device in which the light exit area 62 of the lens 6 is roughened and the roughening 7 represents the means for diffusely scattering light 5. Preferably, the roughening 7 has an average depth of 1 to 2 μm, preferably of 1.5 μm.

A method described here for producing a device in accordance with at least one embodiment is explained in greater detail in conjunction with FIGS. 2a, 2b, 3a and 3b on the basis of schematic sectional illustrations.

FIG. 2a shows a film, serving as a carrier element 9 for the production process. A first stencil 8 is applied on the carrier element 9. By means of an imprint means, which is a doctor blade 12 in this example, the material of the converter element 4 is introduced into the openings of the stencil 8. The material of the converter element 4 can be a layer comprising silicone or composed of a ceramic material into which converter particles are introduced. After the application of the converter element 4 to the stencil 8 by means of screen printing and, if appropriate, curing of the material, the stencil 8 is removed from the carrier element 9 and from the converter element 4. The converter element 4 forms a first layer on the carrier element 9.

In a second step, a second stencil 10 is applied to the carrier element 9 and, by means of a second screen printing process using the doctor blade 12, a means for diffusely scattering light is applied as a second layer 11 to the second stencil 10 by blade coating. The second layer 11 covers the converter element 4 at all exposed outer areas and is in direct contact with the converter element 4, see FIG. 2b. After the application of the second layer 11 to the converter element 4, the second stencil 10 is removed both from the carrier element 9 and from the composite assembly consisting of converter element 4 and the second layer 11.

The second layer 11 can be either a second converter layer or a layer provided with radiation-scattering particles. By way of example, here it is a converter layer that partly converts light emitted by the converter element 4 into light having a different color.

If a second converter layer 11a is involved, the process can be repeated and, in a third or further step, the means for diffusely scattering light 5 is applied to the second converter layer 11a.

As an alternative to the screen printing method described here, a viscous medium can be dripped onto the stencils 8 and/or 10. By means of a spin-coating process, the material is subsequently distributed on the surface of the carrier element 9 and can then cure.

In a last method step, the carrier element 9 is removed from the composite assembly consisting of converter element 4 and the second layer 11, see FIGS. 3a and 3b.

The composite assembly is subsequently applied to the radiation-emitting semiconductor chip 3. Application can take place by means of adhesive bonding, soldering or laminar transfer.

The invention is not restricted by the description on the basis of the exemplary embodiments. Rather, the invention encompasses any novel feature and also any combination of features, which in particular includes any combination of features in the patent claims, even if this feature or this combination itself is not explicitly specified in the patent claims or the exemplary embodiments.

1. An optoelectronic semiconductor device comprising:
at least one radiation-emitting semiconductor chip;
at least one converter element disposed downstream of the semiconductor chip and serving for converting electromagnetic radiation emitted by the semiconductor chip during operation, wherein the converter element emits colored light upon irradiation with ambient light; and
a means for diffusely scattering light, which is designed to scatter ambient light impinging on the device in a switched-off operating state of the device in such a way that a light exit area of the device appears white.

2. The optoelectronic semiconductor device according to claim 1, wherein the means for diffusely scattering light comprises a matrix material into which radiation-scattering particles are introduced.

3. The optoelectronic semiconductor device according to claim 2, wherein the radiation-scattering particles consist of at least one of the following materials or contain one of the following materials: SiO₂, ZrO₂, TiO₂ or AlₓO_{y}.

4. The optoelectronic semiconductor device according to claim 2, wherein the concentration of the radiation-scattering particles in the matrix material is greater than 6% by weight.

5. The optoelectronic semiconductor device according to claim 1, wherein the converter element and the means for diffusely scattering light are in direct contact with one another.

6. The optoelectronic semiconductor device according to claim 5, wherein the means for diffusely scattering light covers the converter element at all exposed outer areas of the converter element.

7. The optoelectronic semiconductor device according to claim 1, wherein the means for diffusely scattering light comprises an optical element, which forms a lens at least in places.

8. The optoelectronic semiconductor device according to claim 1, wherein the means for diffusely scattering light comprises a roughening of a light passage area of a light-transmissive body.

9. The optoelectronic semiconductor device according to claim 1, wherein the means for diffusely scattering light comprises microstructures.

10. The optoelectronic semiconductor device according to claim 1, wherein the means for diffusely scattering light comprises a light-scattering plate, which laterally projects beyond the converter element.

11. The optoelectronic semiconductor device according to claim 1, wherein the means for diffusely scattering light comprises a film applied on an outer area of a lens.

12. A method for producing an optoelectronic semiconductor device according to claim 6, comprising the steps of:
providing a carrier element;
forming the converter element with a first screen printing process on the carrier element;
forming a means for diffusely scattering light onto the exposed outer areas of the converter element with a second screen printing process,
detaching the carrier element; and
applying the composite assembly consisting of the converter element and the means for diffusely scattering light on the radiation-emitting semiconductor chip.
